(19) United States
(12) Patent Application Publication
(10) Pub. No.: US 2024/0061326 A1
(43) Pub. Date: Feb. 22, 2024

(54) RETICLE CONTAINER HAVING PLATING WITH REDUCED EDGE BUILD

(71) Applicant: ENTEGRIS, INC., Billerica, MA (US)

(72) Inventors: Russ V. Raschke, Chanhassen, MN (US); Caleb Elwell, Manitou Springs, CO (US); Brian Wiseman, Glencoe, MN (US)

(21) Appl. No.: 18/233,180

(22) Filed: Aug. 11, 2023

Related U.S. Application Data
(60) Provisional application No. 63/410,550, filed on Sep. 27, 2022.
(60) Provisional application No. 63/398,727, filed on Aug. 17, 2022.

(51) Int. Cl. G03F 1/66; C25D 7/00; C25D 5/10

(52) U.S. Cl. CPC G03F 1/66; C25D 7/00; C25D 5/10

(57) ABSTRACT

Reticle containers include a cover and a baseplate having contact surfaces configured to contact one another when the reticle container is assembled. Relief areas are provided adjacent to at least one of the contact surfaces. The relief areas are such that plating provided on in those relief areas do not contact the other of the cover or the baseplate when the reticle container is assembled. The relief areas can include structures such as beveled regions, depressions, and radiused regions. The relief areas can optionally further serve as a robber during an electroplating process.

### FIELD

This disclosure is directed to reticle containers, particularly reticle containers plated with material such that edge build during plating is reduced.

### BACKGROUND

Reticle containers can be plated, for example to improve surface finish. The plating of the reticle containers can include plating at contact surfaces of the reticle containers. The contact surfaces can be positioned and configured such that the electrical properties and physical structure lead to the generation of edge build during plating, providing regions of increased plating thickness at certain portions of the contact surfaces. These regions of increased plating thickness can be areas experiencing wear, leading to the generation of particulate material, which can contaminate the contents of the reticle container.

### SUMMARY

This disclosure is directed to reticle containers, particularly reticle containers plated with material such that edge build during plating is reduced.

By shaping the cover and/or baseplate of a reticle container such that edge build is reduced by the physical shape and/or electrical properties (serving as a “robber”) of the cover and/or baseplate, the amount of particulate generated by rubbing of the edge build can be reduced, improving the cleanliness of the reticle container. Additionally or alternatively, the cover and/or baseplate can be shaped such that edge build occurs away from contact surfaces and the edge build is not contacted and thus does not contribute significantly to particle generation, again improving the cleanliness of the reticle container. The cleaner reticle containers resulting from addressing edge build during plating in turn improve yield and reduce losses in processing of reticles, such as photolithography including extreme ultraviolet (EUV) photolithography. The reduction in edge build can improve plating processes for reticle container components, allowing plating to be performed successfully with less precise plating devices or control thereof. Additionally, this can simplify plating processes by reducing or removing a need to use external robbers during plating processes.

In an embodiment, a reticle container includes a cover and a baseplate. At least one of the cover or the baseplate includes a base material and a coating layer on said base material. At least one of the cover or the baseplate includes a contact surface and at least one of a first relief area adjacent to at least a portion of an outer perimeter of the contact surface, or a second relief area adjacent to at least a portion of an inner perimeter of the contact surface. Each of the at least one of the first relief area and the second relief area are configured to avoid contact between the cover and the baseplate when the reticle container is assembled such that the cover and the baseplate make contact at the contact surface.

In an embodiment, the first relief area or the second relief area is a region recessed with respect to the contact surface. In an embodiment, the first relief area or the second relief area is a beveled edge. In an embodiment, the first relief area or the second relief surface second relief area includes a radiused region. In an embodiment, a transition from the contact surface to the first relief area or a transition from the contact surface to the second relief area is radiused. In an embodiment, a transition from the contact surface to the second relief area includes a beveled edge. In an embodiment, the first relief area or the second relief area has a depth of at least 0.1 millimeters (mm) with respect to the contact surface.

In an embodiment, the reticle container includes the first relief area and the first relief area surrounds the outer perimeter of the contact surface. In an embodiment, the reticle container includes second relief area and the second relief area is surrounded by the inner perimeter of the contact surface.

In an embodiment, a method of manufacturing a reticle container includes providing a cover and a baseplate. At least one of the cover or the baseplate includes a contact surface and at least one of a first relief area adjacent to at least a portion of an outer perimeter of the contact surface, or a second relief area adjacent to at least a portion of an inner perimeter of the contact surface. The method further includes applying a coating to at least one of the cover or the baseplate. The first relief area and the second relief area are each configured to avoid contact between the cover and the baseplate when the reticle container is assembled such that the cover and the baseplate make contact at the contact surface.

In an embodiment, applying the coating includes electroplating. In an embodiment, at least one of the first relief area and the second relief area serve as a robber during the electroplating. In an embodiment, applying the coating includes multiple discrete applications of the electroplating.

In an embodiment, the first relief area or the second relief area includes a beveled edge. In an embodiment, the first relief area or the second relief area includes a radiused region. In an embodiment, the first relief area or the second relief area is a recess having a depth of at least 0.1 millimeters (mm) with respect to the contact surface.

In an embodiment, the at least one of the cover and the baseplate includes the first relief area, wherein the first relief area surrounds the outer perimeter of the contact surface. In an embodiment, the at least one of the cover and the baseplate includes the second relief area, wherein the second relief area is surrounded by the inner perimeter of the contact surface.

### DRAWINGS

FIG. 1 shows an exploded view of a reticle container according to an embodiment.

FIG. 2 shows a perspective view of a cover of a reticle container according to an embodiment.

FIG. 3 shows a perspective view of a baseplate of a reticle container according to an embodiment.

FIG. 4 shows a sectional view of a reticle container according to an embodiment.

FIG. 5 shows a sectional view of a reticle container according to an embodiment.

FIG. 6 shows a flowchart of a method according to an embodiment.

### DETAILED DESCRIPTION

This disclosure is directed to reticle containers, particularly reticle containers plated with material such that edge build during plating is reduced.

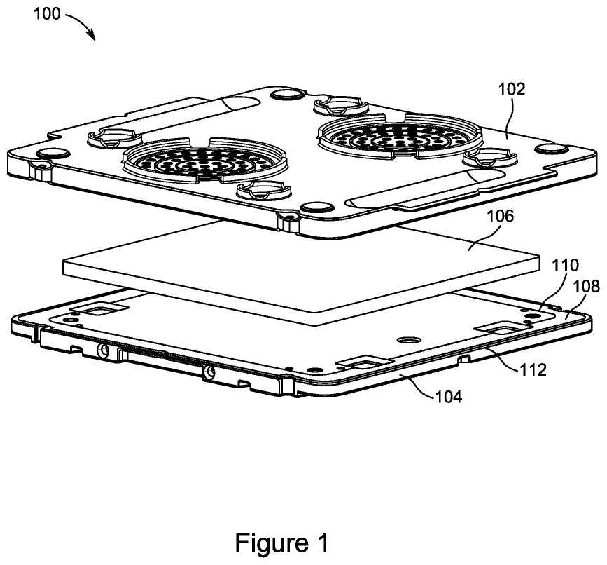

FIG. 1 shows an exploded view of a reticle container according to an embodiment. Reticle container 100 includes cover 102 and baseplate 104. Reticle 106 can be contained within an internal space defined by the cover 102 and the baseplate 104. Cover 102 includes cover contact surface (not shown) and baseplate 104 includes baseplate contact surface 108. Baseplate 104 includes a first relief area 110 and second relief area 112.

Reticle container 100 is a container configured to accommodate a reticle 106, such as a reticle for processing such as photolithography, for example extreme ultraviolet (EUV) processing. The reticle container 100 can be used to transport and/or store the reticle. In an embodiment, the reticle container 100 is an EUV reticle container. In an embodiment, the reticle container 100 is a stocker pod for storage of reticle 106 prior to, during, or after processing. In an embodiment, the reticle container 100 can be received at a load port of an EUV processing device to be opened and for the reticle 106 to be added to or removed from the reticle container 100. The reticle container 100 contains the reticle 106 in an internal space within the reticle container 100.

Cover 102 forms a first container segment of the reticle container 100. The cover 102 forms part of an internal space configured to accommodate the reticle 106. At least some surfaces of cover 102 can be formed by plating of a material onto a base material of the cover 102.

Baseplate 104 forms a second container segment of the reticle container 100. The baseplate 104, when combined with cover 102 forms the internal space capable of accommodating reticle 106. At least some surfaces of baseplate 104 can be formed by plating of a material onto a base material of the cover 102.

Reticle 106 is a reticle contained within reticle container 100. The reticle 106 can be any suitable reticle, such as a reticle being processed by methods such as photolithography including extreme ultraviolet (EUV) photolithography.

Baseplate contact surface 108 is a surface of baseplate 104 configured to contact corresponding surfaces on the cover 102 when reticle container 100 is assembled.

First relief area 110 can be positioned outside the baseplate contact surface 108. The first relief area 110 can be configured so as to avoid the cover 102 when the reticle container 100 is assembled. The avoidance of cover 102 can include avoidance of contact between edge build of plating provided on either or both of cover 102 and baseplate 104. The size and shape of first relief area 110 can be any suitable shape and size so as to achieve the avoidance of cover 102. For example, the first relief area 110 can be a groove or depression in the surface of baseplate 104. In an embodiment, the first relief area 110 is a depression having a depth of at least 0.1 millimeters (mm) with respect to the contact surface and a width in a range from 2 mm to 4 mm. In an embodiment, the first relief area 110 includes a beveled edge. In an embodiment, a transition from the baseplate contact surface 108 to the first relief area 110 is radiused. In an embodiment, the first relief area 110 can be spaced apart from baseplate contact surface 108. In an embodiment, the first relief area 110 is directly adjacent to the baseplate contact surface 108. In an embodiment, the first relief area 110 is electrically connected to the baseplate contact surface 108.

Second relief area 112 is positioned inside of the baseplate contact surface 108. The second relief area 112 can be configured so as to avoid the cover 102 when the reticle container 100 is assembled. The avoidance of cover 102 can include avoidance of contact between edge build of plating provided on either or both of cover 102 and baseplate 104. For example, the second relief area 112 can be a groove or depression in the surface of baseplate 104. The size and shape of second relief area 112 can be any suitable shape and size so as to achieve the avoidance of cover 102. In an embodiment, the second relief area 112 is a depression having a depth of at least 0.1 millimeters (mm) with respect to the contact surface and a width in a range from 2 mm to 4 mm. In an embodiment, the second relief area 112 includes a beveled edge. In an embodiment, a transition from the baseplate contact surface 108 to the second relief area 112 is radiused. In an embodiment, the second relief area 112 can be spaced apart from baseplate contact surface 108. In an embodiment, the second relief area 112 is directly adjacent to the baseplate contact surface 108. In an embodiment, the second relief area 112 is electrically connected to the baseplate contact surface 108.

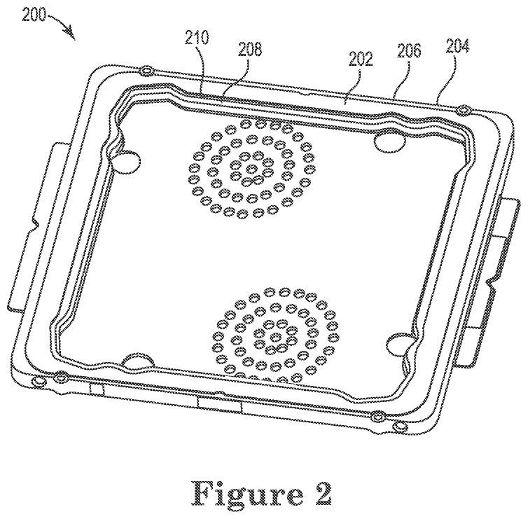

FIG. 2 shows a perspective view of a cover of a reticle container according to an embodiment. Cover 200 includes cover contact surface 202, first relief area 204, first transition 206, second relief area 208, and second transition 210.

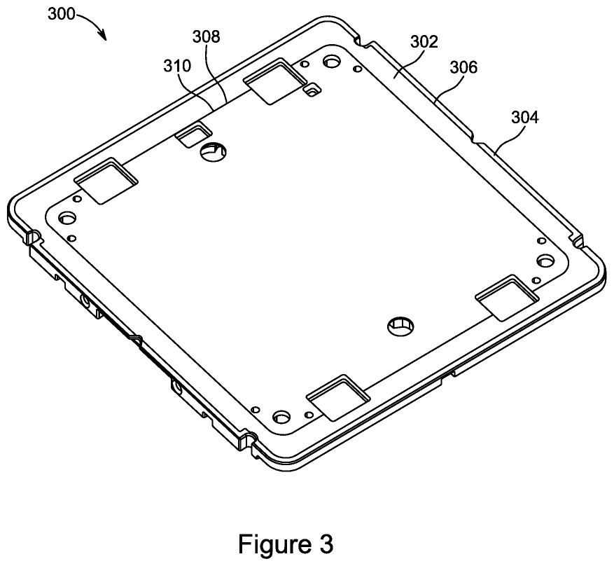

Cover 200 is a cover of a reticle container. Cover 200 is configured such that when combined with a baseplate, such as baseplate 300 described below and shown in FIG. 3, an internal space is defined, with the internal space being capable of accommodating a reticle.

Cover contact surface 202 can be provided outside of the part of cover 200 defining the internal space. Cover contact surface 202 is configured to contact a baseplate when a reticle container including cover 200 is assembled. In an embodiment, the cover contact surface 202 can be a continuous flat surface. In an embodiment, the cover contact surface 202 can include a plurality of regions of flat surfaces each configured to contact the baseplate. The cover contact surface 202 can include surfaces that are formed of a material that is plated onto a base material of the cover 200.

First relief area 204 is positioned outside the cover contact surface 202. In an embodiment, the first relief area 204 can be positioned adjacent to at least portions of the cover contact surface 202. In an embodiment, the first relief area 204 can surround the exterior of cover contact surface 202. The first relief area 204 is a region of cover 200 configured to avoid contact with the baseplate when cover 200 is assembled with the baseplate to form a reticle container, such as reticle container 100 shown in FIG. 1 and described above. The avoidance of the baseplate by first relief area 204 can include avoidance of contact between edge build of plating formed on one or both of the cover 200 and the baseplate. The first relief area 204 can include a region recessed with respect to the cover contact surface 202. In an embodiment, the first relief area 204 is a depression having a depth of at least 10 micrometers (μm) relative to cover contact surface 202 and a width of at least 50 μm. In an embodiment, the first relief area 204 is a depression having a depth of at least 0.1 millimeters (mm) with respect to the cover contact surface 202 and a width in a range from 2 mm to 4 mm. In an embodiment, the first relief area 204 is a surface angled with respect to the cover contact surface 202 so as to form a beveled edge adjacent to at least a portion of cover contact surface 202. In an embodiment, the first relief area 204 can be spaced apart from cover contact surface 202. In an embodiment, the first relief area 204 is directly adjacent to the cover contact surface 202. In an embodiment, the first relief area 204 and the cover contact surface 202 are electrically connected to one another.

First transition 206 is the transition from the cover contact surface 202 to the first relief area 204. In an embodiment, first transition 206 is a step from the cover contact surface 202 to the relatively recessed first relief area 204. In an embodiment, first transition 206 is a corner where the beveled surface of first relief area 204 intersects the cover contact surface 202. In an embodiment, first transition 206 can include radiusing, for example at one or more corners included in or formed by the first transition 206.

Second relief area 208 is positioned inside the cover contact surface 202. In an embodiment, the second relief area 208 can be positioned adjacent to at least a portion of the cover contact surface 202. In an embodiment, the second relief area 208 can be surrounded by the interior of cover contact surface 202. The second relief area 208 is a region of cover 200 configured to avoid contact with the baseplate when cover 200 is assembled with the baseplate to form a reticle container, such as reticle container 100 shown in FIG. 1 and described above. The avoidance of the baseplate by second relief area 208 can include avoidance of contact between edge build of plating formed on one or both of the cover 200 and the baseplate. The second relief area 208 can include a region recessed with respect to the cover contact surface 202. In an embodiment, the first relief area 204 is a depression having a depth of at least 10 micrometers (μm) relative to cover contact surface 202. In an embodiment, the second relief area 208 is a depression having a depth of at least 0.1 millimeters (mm) with respect to the cover contact surface 202. In an embodiment, the second relief area 208 is a surface angled with respect to the cover contact surface 202 so as to form a beveled edge surrounding at least a portion of cover contact surface 202. In an embodiment, the second relief area 208 can be spaced apart from cover contact surface 202. In an embodiment, the second relief area 208 is directly adjacent to the cover contact surface 202. In an embodiment, the second relief area 208 and the cover contact surface 202 are electrically connected to one another.

Second transition 210 is the transition from the cover contact surface 202 to the second relief area 208. In an embodiment, second transition 210 is a step from the cover contact surface 202 to the relatively recessed second relief area 208. In an embodiment, second transition 210 is a corner where the beveled surface of second relief area 208 intersects the cover contact surface 202. In an embodiment, second transition 210 can include radiusing, for example at one or more corners included in or formed by the second transition 210.

FIG. 3 shows a perspective view of a baseplate of a reticle container according to an embodiment. Baseplate 300 includes baseplate contact surface 302, first relief area 304, first transition 306, second relief area 308, and second transition 310.

Baseplate contact surface 302 can be provided outside of the part of baseplate 300 that defines the internal space when baseplate 300 is joined to a cover, such as cover 200 described above and shown in FIG. 2. Baseplate contact surface 302 is configured to contact a cover, for example at a cover contact surface such as cover contact surface 202 as described above and shown in FIG. 2 when a reticle container including baseplate 300 is assembled. In an embodiment, the baseplate contact surface 302 can be a continuous flat surface. In an embodiment, the baseplate contact surface 302 can include a plurality of regions of flat surfaces each configured to contact the cover. The baseplate contact surface 302 can include surfaces that are formed of a material that is plated onto a base material of the baseplate 300.

First relief area 304 is positioned outside the baseplate contact surface 302. In an embodiment, the first relief area 304 can be positioned immediately outside of the baseplate contact surface 302. In an embodiment, the first relief area 304 can surround the exterior of baseplate contact surface. The first relief area 304 is a region of baseplate 300 configured to avoid contact with the cover when baseplate 300 is assembled with the cover to form a reticle container, such as reticle container 100 shown in FIG. 1 and described above. The avoidance of the cover by first relief area 304 can include avoidance of contact between edge build of plating formed on one or both of the cover and the baseplate 300. The first relief area 304 can include a region recessed with respect to the baseplate contact surface 302. In an embodiment, the first relief area 304 is a depression having a depth of at least 0.1 millimeters (mm) with respect to the baseplate contact surface 302 and a width in a range from 2 mm to 4 mm. In an embodiment, the first relief area 304 is a surface angled with respect to the baseplate contact surface 302 so as to form a beveled edge surrounding baseplate contact surface 302.

First transition 306 is the transition from the baseplate contact surface 302 to the first relief area 304. In an embodiment, first transition 306 is a step from the baseplate contact surface 302 to the relatively recessed first relief area 304. In an embodiment, second transition 310 is a corner where the beveled surface of first relief area 304 intersects the baseplate contact surface 302. In an embodiment, first transition 306 can include radiusing, for example at one or more corners included in or formed by the first transition 306.

Second relief area 308 is positioned inside the baseplate contact surface 302. In an embodiment, the second relief area 308 can be positioned immediately inside of the baseplate contact surface 302. In an embodiment, the second relief area 308 can be surrounded by the interior of baseplate contact surface 302. The second relief area 308 is a region of baseplate 300 configured to avoid contact with the cover when baseplate 300 is assembled with the cover to form a reticle container, such as reticle container 100 shown in FIG. 1 and described above. The avoidance of the cover by second relief area 308 can include avoidance of contact between edge build of plating formed on one or both of the cover and the baseplate 300. The second relief area 308 can include a region recessed with respect to the baseplate contact surface 302. In an embodiment, the second relief area 308 is a depression having a depth of at least 0.1 millimeters (mm) with respect to the baseplate contact surface 302 and a width in a range from 2 mm to 4 mm. In an embodiment, the second relief area 308 is a surface angled with respect to the baseplate contact surface 302 so as to form a beveled edge surrounding baseplate contact surface 302.

Second transition 310 is the transition from the baseplate contact surface 302 to the second relief area 308. In an embodiment, second transition 310 is a step from the baseplate contact surface 302 to the relatively recessed second relief area 308. In an embodiment, second transition 310 is a corner where the beveled surface of second relief area 308 intersects the baseplate contact surface 302. In an embodiment, second transition 310 can include radiusing, for example at one or more corners included in or formed by the second transition 310.

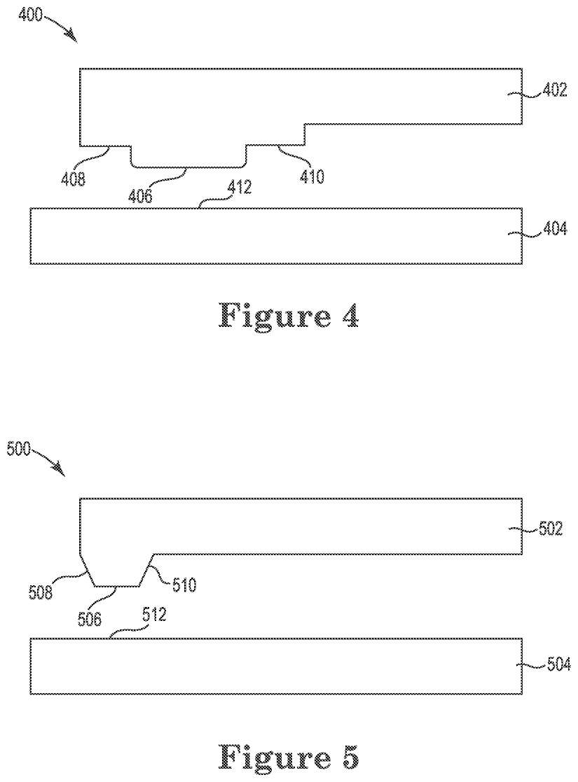

FIG. 4 shows a sectional view of a reticle container according to an embodiment. Reticle container 400 includes cover 402 and baseplate 404. Cover 402 includes a cover contact surface 406, a first relief area 408, and a second relief area 410. Baseplate 404 includes baseplate contact surface 412.

Cover 402 forms a portion of reticle container 400. When combined with baseplate 404, cover 402 and baseplate 404 define an internal space configured to accommodate a reticle. The cover 402 includes cover contact surface 406. Cover contact surface 406 is a portion of cover 402 configured to contact baseplate 404 when the reticle container 400 is assembled. Cover contact surface 406 can be one or more flat surfaces positioned such that the one or more flat surfaces are towards the baseplate 404. The cover contact surface 406 can be a plated surface formed on a base material of cover 402.

First relief area 408 is provided on an outer side of the cover contact surface 406. The first relief area 408 is on a side of cover contact surface 406 opposite from the internal space defined by cover 402 and baseplate 404. In the embodiment shown in FIG. 4, the first relief area 408 is a region that is recessed with respect to cover contact surface 406. In an embodiment, the first relief area 408 can have a depth of at least 0.1 millimeters (mm) with respect to the cover contact surface 406 and a width in a range from 2 mm to 4 mm. As shown in FIG. 4, the transition from the cover contact surface 406 to the first relief area 408 can be radiused, with the radiusing at the corner formed where first relief area 408 is recessed from cover contact surface 406. In an embodiment, the transition from the cover contact surface 406 to first relief area 408 can include a beveled edge, a sharp corner, or the like.

Second relief area 410 is provided on an inner side of the cover contact surface 406. The second relief area 410 is on a side of cover contact surface 406 towards the internal space defined by cover 402 and baseplate 404. In the embodiment shown in FIG. 4, the second relief area 410 is a region that is recessed with respect to cover contact surface 406. In an embodiment, the second relief area 410 can have a depth of at least 0.1 millimeters (mm) with respect to the cover contact surface 406 and a width in a range from 2 mm to 4 mm. As shown in FIG. 4, the transition from the cover contact surface 406 to the second relief area 410 can be radiused, with the radiusing at the corner formed where second relief area 410 is recessed from cover contact surface 406. In an embodiment, the transition from the cover contact surface 406 to second relief area 410 can include a beveled edge, a sharp corner, or the like.

Baseplate 404 is configured to be joined to cover 402 to form the reticle container 400. The baseplate 404 includes baseplate contact surface 412, which is configured to contact cover contact surface 406 when the cover 402 is joined to baseplate 404. The baseplate contact surface 412 is a flat area positioned to correspond to the position of the cover contact surface 406.

While FIG. 4 shows the first relief area 408 and the second relief area 410 as being provided around cover contact surface 406, it is understood that corresponding relief areas can instead or additionally be formed about the baseplate contact surface 412. Relief areas can be provided on baseplate 404, inside and outside of the baseplate contact surface 412 by, for example, providing trenches or grooves inside and outside of the baseplate contact surface 412.

FIG. 5 shows a sectional view of a reticle container according to an embodiment. Reticle container 500 includes cover 502 and baseplate 504. Cover 502 includes a cover contact surface 506, a first relief area 508, and a second relief area 510. Baseplate 504 includes baseplate contact surface 512.

Cover 502 forms a portion of reticle container 500. When combined with baseplate 504, cover 502 and baseplate 504 define an internal space configured to accommodate a reticle. The cover 502 includes cover contact surface 506. Cover contact surface 506 is a portion of cover 502 configured to contact baseplate 504 when the reticle container 500 is assembled. Cover contact surface 506 can be one or more flat surfaces positioned such that the one or more flat surfaces are towards the baseplate 504. The cover contact surface 506 can be a plated surface formed on a base material of cover 502.

First relief area 508 is provided on an outer side of the cover contact surface 506. The first relief area 508 is on a side of cover contact surface 506 away from the internal space defined by cover 502 and baseplate 504. In the embodiment shown in FIG. 5, the first relief area 508 is a surface angled with respect to cover contact surface 506 such that the first relief area 508 provides a beveled edge surrounding the contact surface 506. The angle can be any suitable angle allowing first relief area 508 to avoid contact with the baseplate 504, including avoiding contact between plating such as edge buildup of plating on one or both of cover 502 and baseplate 504. As shown in FIG. 5, the transition from the cover contact surface 506 to the first relief area 508 can be a corner formed by the intersection of cover contact surface 506 and first relief area 508. In an embodiment, the transition from cover contact surface 506 to the first relief area 508 can be radiused.

Second relief area 510 is provided on an inner side of the cover contact surface 506. The second relief area 510 is on a side of cover contact surface 506 towards the internal space defined by cover 502 and baseplate 504. In the embodiment shown in FIG. 5, the second relief area 510 is a surface angled with respect to cover contact surface 506 such that the second relief area 510 provides a beveled edge surrounding the contact surface 506. The angle can be any suitable angle allowing second relief area 510 to avoid contact with the baseplate 504, including avoiding contact between plating such as edge buildup of plating on one or both of cover 502 and baseplate 504. As shown in FIG. 5, the transition from the cover contact surface 506 to the second relief area 510 can be a corner formed by the intersection of cover contact surface 506 and second relief area 510. In an embodiment, the transition from cover contact surface 506 to the second relief area 510 can be radiused.

Baseplate 504 is configured to be joined to cover 502 to form the reticle container 500. The baseplate 504 includes baseplate contact surface 512, which is configured to contact cover contact surface 506 when the cover 502 is joined to baseplate 504. The baseplate contact surface 512 is a flat area positioned to correspond to the position of the cover contact surface 506.

While FIG. 5 shows the first relief area 508 and the second relief area 510 as being provided around cover contact surface 506, it is understood that corresponding relief areas can instead or additionally be formed about the baseplate contact surface 512. Relief areas can be provided on baseplate 504, inside and outside of the baseplate contact surface 512 by, for example, providing trenches or grooves inside and outside of the baseplate contact surface 512.

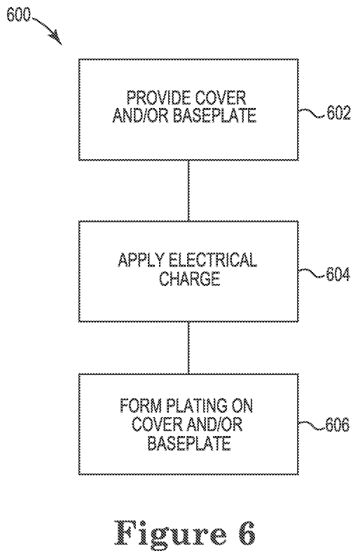

FIG. 6 shows a flowchart of a method according to an embodiment. Method 600 includes providing a cover or a baseplate 602, applying an electrical charge to the cover or baseplate 604, and plating the cover or the baseplate 606. In embodiments, the method 600 can be applied to both a cover of a reticle container and a baseplate of a reticle container.

The cover or baseplate provided at 602 can include a contact surface, a first relief area outside of the contact surface, and a second relief area inside of the contact surface. In an embodiment, the cover or baseplate provided at 602 is a solid piece of a base material. A non-limiting example of a base material is aluminum. In an embodiment, a cover such as cover 200 shown in FIG. 2 and described above can be provided at 602. In an embodiment, a baseplate such as baseplate 300 shown in FIG. 3 and described above can be provided at 602. The contact surface and the first and second relief areas on the cover or baseplate provided at 602 can be according to any of the contact surfaces and relief areas described herein, including, but not limited to regions recessed from the contact surfaces, beveled edges, and the like. In an embodiment, transitions from the contact surface to the first relief area and/or the second relief area can be radiused.

An electrical charge is applied to the cover or baseplate at 604. The electrical charge can be supplied through any suitable means for electroplating. During the application of the electrical charge to the cover or baseplate at 604, features such as the first relief area and/or the second relief area can affect the distribution of charge within the cover or baseplate. In an embodiment, the first relief area and/or the second relief area serve as a robber, reducing charge at boundaries of the contact surface and thus resulting in less plating forming at the edges of the contact surface.

In an embodiment, the first relief area has a plating with a first depth and the contact area between the cover and baseplate has plating with a second depth, where the second depth is less than the first depth. The second relief area may have plating with a third depth, where the second depths is less than the third depth. In some embodiments, the plating on the relief area serves to make the plating on the contact area more uniform in thickness. The relief areas may inhibit the preferential deposition of plated material on the edges of the contact area. This may allow for a flatter and more uniform contact area compared with plated contact areas which lack proximal relief areas.

The first and second relief areas may be in electrical communication with the contact area. For example, the first and second relief areas may have a shared potential applied to the first and second relief areas and the contact area during plating. The current per unit of surface area will tend to be higher at the relief areas compared with the contact area. This greater current per unit area may be associated with a relative increase in plated material during the plating of the cover or baseplate. Because the relief areas are at the edge of the plated area, they will tend to accumulate greater amounts of plated material. In contrast, the contact area will tend to have more uniform deposition due to the presence of the relief areas.

Plating is applied to the cover or the baseplate at 606. The plating forms on the cover or baseplate through electroplating resulting from the application of charge to the cover or baseplate at 604. Where the first relief area and/or the second relief area serve as a robber, the buildup of plating at edges of the contact surface can be reduced due to the reduction in charge at the boundaries of the contact surface. In an embodiment, the application of plating to the cover or the baseplate at 606 can include multiple steps of plating. In an embodiment, the plating applied to the cover or the baseplate at 606 can include one or more of EN plating, bright nickel plating, and/or chrome

### ASPECTS

It is understood that any of aspects 1-9 can be combined with any of aspects 10-20.

Aspect 1. A reticle container, comprising a cover and a baseplate, wherein:
at least one of the cover or the baseplate includes a base material and a coating layer on said base material,
at least one of the cover or the baseplate includes a contact surface and at least one of:
   a first relief area adjacent to at least a portion of an outer perimeter of the contact surface, or
   a second relief area adjacent to at least a portion of an inner perimeter of the contact surface, and
each of the at least one of the first relief area and the second relief area are configured to avoid contact between the cover and the baseplate when the reticle container is assembled such that the cover and the baseplate make contact at the contact surface.

Aspect 2. The reticle container according to aspect 1, wherein the first relief area or the second relief area is a region recessed with respect to the contact surface.

Aspect 3. The reticle container according to aspect 1, wherein the first relief area or the second relief area is a beveled edge.

Aspect 4. The reticle container according to aspect 1, wherein the first relief area or the second relief surface second relief area includes a radiused region.

Aspect 5. The reticle container according to any of aspects 1-4, wherein a transition from the contact surface to the first relief area or a transition from the contact surface to the second relief area is radiused.

Aspect 6. The reticle container according to any of aspects 1-5, wherein a transition from the contact surface to the second relief area includes a beveled edge.

Aspect 7. The reticle container according to any of aspect 1-6, wherein the first relief area or the second relief area has a depth of at least 0.1 millimeters (mm) with respect to the contact surface.

Aspect 8. The reticle container according to any of aspects 1-7, including the first relief area and wherein the first relief area surrounds the outer perimeter of the contact surface.

Aspect 9. The reticle container of claim 1, including the second relief area and wherein the second relief area is surrounded by the inner perimeter of the contact surface.

Aspect 10. A method of manufacturing a reticle container, comprising:
providing a cover and a baseplate, wherein at least one of the cover or the baseplate includes a contact surface and at least one of:
a first relief area adjacent to at least a portion of an outer perimeter of the contact surface, or
a second relief area adjacent to at least a portion of an inner perimeter of the contact surface; and
applying a coating to at least one of the cover or the baseplate,
wherein each of the at least one of the first relief area and the second relief area are configured to avoid contact between the cover and the baseplate when the reticle container is assembled such that the cover and the baseplate make contact at the contact surface.

Aspect 11. The method according to aspect 10, wherein applying the coating includes electroplating.

Aspect 12. The method according to aspect 11, wherein at least one of the first relief area and the second relief area serve as a robber during the electroplating.

Aspect 13. The method according to aspect 11, wherein applying the coating includes multiple discrete applications of the electroplating.

Aspect 14. The method according to any of aspects 10-13, wherein the first relief area or the second relief area includes a beveled edge.

Aspect 15. The method according to any of aspects 10-14, wherein the first relief area or the second relief area includes a radiused region.

Aspect 16. The method according to any of aspects 10-15, wherein the first relief area or the second relief area is a recess having a depth of at least 0.1 millimeters (mm) with respect to the contact surface.

Aspect 17. The method according to any of aspects 10-16, wherein the at least one of the cover and the baseplate includes the first relief area, wherein the first relief area surrounds the outer perimeter of the contact surface.

Aspect 18. The method according to any of aspects 10-17, wherein the at least one of the cover and the baseplate includes the second relief area, wherein the second relief area is surrounded by the inner perimeter of the contact surface.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. A reticle container, comprising a cover and a baseplate, wherein:
at least one of the cover or the baseplate includes a base material and a coating layer on said base material,
at least one of the cover or the baseplate includes a contact surface and at least one of:
a first relief area adjacent to at least a portion of an outer perimeter of the contact surface, or
a second relief area adjacent to at least a portion of an inner perimeter of the contact surface, and
each of the at least one of the first relief area and the second relief area are configured to avoid contact between the cover and the baseplate when the reticle container is assembled such that the cover and the baseplate make contact at the contact surface.

2. The reticle container of claim 1, wherein the first relief area or the second relief area is a region recessed with respect to the contact surface.

3. The reticle container of claim 1, wherein the first relief area or the second relief area is a beveled edge.

4. The reticle container of claim 1, wherein the first relief area or the second relief surface second relief area includes a radiused region.

5. The reticle container of claim 1, wherein a transition from the contact surface to the first relief area or a transition from the contact surface to the second relief area is radiused.

6. The reticle container of claim 1, wherein a transition from the contact surface to the second relief area includes a beveled edge.

7. The reticle container of claim 1, wherein the first relief area or the second relief area has a depth of at least 0.1 millimeters (mm) with respect to the contact surface.

8. The reticle container of claim 1, including the first relief area and wherein the first relief area surrounds the outer perimeter of the contact surface.

9. The reticle container of claim 1, including the second relief area and wherein the second relief area is surrounded by the inner perimeter of the contact surface.

10. A method of manufacturing a reticle container, comprising:
providing a cover and a baseplate, wherein at least one of the cover or the baseplate includes a contact surface and at least one of:
a first relief area adjacent to at least a portion of an outer perimeter of the contact surface, or
a second relief area adjacent to at least a portion of an inner perimeter of the contact surface; and
applying a coating to at least one of the cover or the baseplate,
wherein the first relief area and the second relief area are each configured to avoid contact between the cover and the baseplate when the reticle container is assembled such that the cover and the baseplate make contact at the contact surface.

11. The method of claim 10, wherein applying the coating includes electroplating.

12. The method of claim 11, wherein at least one of the first relief area and the second relief area serve as a robber during the electroplating.

13. The method of claim 11, wherein applying the coating includes multiple discrete applications of the electroplating.

14. The method of claim 10, wherein the first relief area or the second relief area includes a beveled edge.

15. The method of claim 10, wherein the first relief area or the second relief area includes a radiused region.

16. The method of claim 10, wherein the first relief area or the second relief area is a recess having a depth of at least 0.1 millimeters (mm) with respect to the contact surface.

17. The method of claim 10, wherein the at least one of the cover and the baseplate includes the first relief area, wherein the first relief area surrounds the outer perimeter of the contact surface.

18. The method of claim 10, wherein the at least one of the cover and the baseplate includes the second relief area, wherein the second relief area is surrounded by the inner perimeter of the contact surface.
